(19) United States
(12) Patent Application Publication
(10) Pub. No.: US 2009/0283139 A1
(43) Pub. Date: Nov. 19, 2009

(54) SEMICONDUCTOR STRUCTURE COMBINATION FOR THIN-FILM SOLAR CELL AND MANUFACTURE THEREOF

(76) Inventors: Miin-Jang CHEN, Taipei City (TW); Wen-Ching Hsu, Hsinchu City (TW); Suz-Hua Ho, Jhudong Township (TW)

Correspondence Address: BIRCH STEWART KOLASCH & BIRCH, PO BOX 747, FALLS CHURCH, VA, 22040-0747, US

(21) Appl. No.: 12/465,087

(22) Filed: May 13, 2009

(30) Foreign Application Priority Data
May 14, 2008 (TW) 097117665

(51) Int. Cl. H01L 31/04; H01L 31/0216

(52) U.S. Cl. 136/255; 438/57; 257/E31.119

(57) ABSTRACT

The invention discloses a semiconductor structure combination for a thin-film solar cell and a manufacture thereof. The semiconductor structure combination according to the invention includes a substrate, a multi-layer structure, and a passivation layer. The substrate has an upper surface. The multi-layer structure is deposited on the upper surface of the substrate and includes a p-n junction, a p-i-n junction, an n-i-p junction, a tandem junction or a multi-junction. The passivation layer is deposited by an atomic layer deposition process and/or a plasma-enhanced (or a plasma-assisted) atomic layer deposition process on a top-most layer of the multi-layer structure.

### BACKGROUND OF THE INVENTION

1. Field of the Invention

The present invention relates to a semiconductor structure combination and a manufacture thereof. More particularly, the present invention relates to a semiconductor structure combination for a thin-film solar cell.

2. Description of the Prior Art

Solar cells are extensively employed because of being capable of converting the accessible energy, emitted from a light source such as the sun, to electricity to operate electronic equipments such as calculators, computers, and heaters.

The principle of the solar cells can be explained as follows. Each photon of the light penetrates into and is absorbed by a silicon substrate, for transferring its energy to an electron in a bound state (covalent bond) and thereby releasing a bound electron to be a free one. The movable electrons and the holes lead to a current flow in the solar cells. In order to contribute to the current, the electrons and holes cannot recombine with each other but rather are separated by the electric field associated with the p-n junction inside the silicon substrate.

It is known that the formation of a passivation layer on the surface of the solar cell can decrease the carrier recombination at the surface.

At present, solar cells are mainly made of silicon. Based on the different crystal structures, solar cells can be divided into single-crystal silicon solar cells, polycrystal silicon solar cells, and amorphous silicon solar cells (i.e. thin-film solar cells).

In general, the amorphous silicon is deposited, by the plasma enhanced chemical vapor deposition (PECVD), on a substrate (e.g. a glass substrate) to grow a layer of amorphous silicon thin film. Since the absorption coefficient of the amorphous silicon is higher than that of the single-crystal silicon, only a quite thin layer of the amorphous silicon is required to effectively absorb the light. The advantage of the amorphous silicon solar cell is that cheaper substrates, such as glass, ceramic, or metal substrates, can be used instead of expensive crystalline silicon substrates, which reduces the material cost greatly and makes it possible for productions of large-dimension solar cells. In contrast, the dimension of the crystalline silicon solar cell is limited by the size of the silicon wafer.

For the large-dimension amorphous silicon solar cell, a passivation layer on the surface of the solar cell is also needed to decrease the carrier recombination at the surface. Therefore, to solve the aforementioned problems, the main scope of the invention is to provide a semiconductor structure combination for a thin-film solar cell and a manufacture thereof.

### SUMMARY OF THE INVENTION

One scope of the invention is to provide a semiconductor structure combination for a thin-film solar cell and a manufacture thereof.

According to an embodiment of the invention, the semiconductor structure combination includes a substrate, a multi-layer structure, and a passivation layer.

The substrate has an upper surface. The multi-layer structure is deposited on the upper surface of the substrate and includes a p-n junction, a p-i-n junction, an n-i-p junction, a tandem junction or a multi-junction. The passivation layer is deposited by an atomic layer deposition process and/or a plasma-enhanced (or a plasma-assisted) atomic layer deposition process on a top-most layer of the multi-layer structure.

It is related to a method of fabricating a semiconductor structure combination for a thin-film solar cell according to another embodiment of the invention.

First, a substrate having an upper surface is prepared. Subsequently, a multi-layer structure is deposited on the upper surface of the substrate and includes a p-n junction, a p-i-n junction, an n-i-p junction, a tandem junction or a multi-junction. Afterwards, by an atomic layer deposition process and/or a plasma-enhanced (or a plasma-assisted) atomic layer deposition process, a passivation layer is deposited on a top-most layer of the multi-layer structure.

Compared to the prior art, inside the semiconductor structure combination for the thin-film solar cell according to the invention, the high-quality surface passivation layer can be deposited, by the atomic layer deposition process, on the silicon thin film with an excellent deposition uniformity and an excellent three-dimensional conformality, to eliminate the effect of dangling bonds and defects. In particular, for the silicon thin film consisting of pinholes and microcrystalline structures, the passivation layer can be deposited, due to the excellent three-dimensional conformality of the atomic layer deposition process, between the pinholes and grain boundaries of the microcrystalline structures in the silicon thin film layer to function effectively.

The advantage and spirit of the invention may be understood by the following recitations together with the appended drawings.

### BRIEF DESCRIPTION OF THE APPENDED DRAWINGS

FIG. 1 illustrates a sectional view of the semiconductor structure combination according to the invention.

FIG. 2 illustrates a sectional view of a thin-film solar cell according to a first embodiment of the invention.

FIG. 3 illustrates a sectional view of a thin-film solar cell according to a second embodiment of the invention.

FIG. 4 illustrates a sectional view of a thin-film solar cell according to a third embodiment of the invention.

FIGS. 5A through 5C illustrate sectional views for describing the method of fabricating a semiconductor structure combination according to another embodiment of the invention.

### DETAILED DESCRIPTION OF THE INVENTION

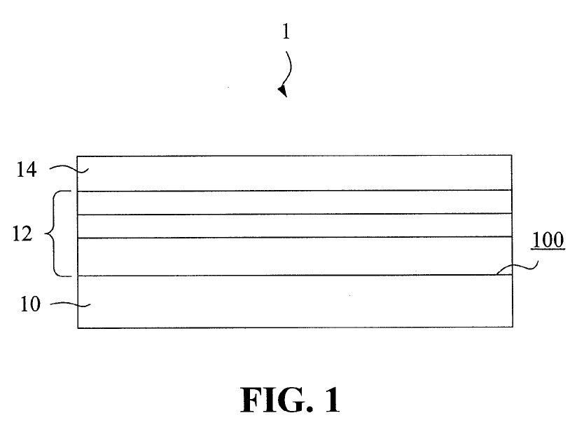

Please refer to FIG. 1. FIG. 1 illustrates a sectional view of the semiconductor structure combination according to the invention. The semiconductor structure combination 1 can be used for a thin-film solar cell, but not limited herein.

As shown in FIG. 1, the semiconductor structure combination 1 includes a substrate 10, a multi-layer structure 12, and a passivation layer 14. In practical applications, the substrate 10 can be a transparent and insulating substrate 10. For example, the substrate 10 can be made of glass, but not limited herein. The substrate 10 has an upper surface 100. The multi-layer structure 12 is deposited on the upper surface 100 of the substrate 10.

In practical applications, the multi-layer structure 12 can include a p-i-n junction (i means the intrinsic silicon without an n-type or a p-type dopant), an n-i-p junction, a tandem junction or a multi-junction. The passivation layer 14 can be deposited on a top-most layer of the multi-layer structure 12.

In practical applications, the passivation layer 14 can be deposited by an atomic layer deposition process and/or a plasma-enhanced (or a plasma-assisted) atomic layer deposition process on the top-most layer of the multi-layer structure 12.

Please refer to table 1 below. Table 1 illustrates a look-up table of the compositions and the precursors of the passivation layer 14. As shown in table 1, in practical applications, the passivation layer 14 can be made of Al₂O₃ [symbol] AlN [symbol] HfO₂ [symbol] Hf₃N₄ [symbol] Si₃N₄ [symbol] SiO₂ [symbol] Ta₂O₅ [symbol] TiO₂ [symbol] TiN [symbol] ZnO [symbol] ZrO₂ [symbol] Zr₃N₄, other similar compounds, or a mixture of the aforementioned compounds, but not limited herein.

TABLE 1

| Composition | Precursors |
|---|---|
| Al₂O₃ | AlCl₃ + H₂O; AlBr₃ + H₂O; AlCl₃ + O₂; AlCl₃ + O₃; AlCl₃ + ROH; |
| | Al(CH₃)₃ + H₂O; Al(CH₃)₃ + H₂O₂; Al(CH₃)₃ + N₂O; Al(CH₃)₃ + NO₂; |
| | Al(CH₃)₃ + O₂-plasma; Al(C₂H₅)₃ + H₂O; Al(OC₂H₅)₃ + H₂O/ROH; |
| | Al(OCH₂CH₂CH₃)₃ + H₂O/ROH; AlCl₃ + Al(OC₂H₅)₃; |
| | AlCl₃ + Al(OCH(CH₃)₂)₃; Al(CH₃)₃ + Al(OCH(CH₃)₂)₃; |
| | Al(CH₃)₂Cl + H₂O; Al(CH₃)₂H + H₂O; Al[OCH(CH₃)C₂H₅]₃ + H₂O; |
| | Al(N(C₂H₅)₂)₃ + H₂O; Al(NCH₃(C₂H₅))₃ + H₂O |
| AlN | AlCl₃+ NH₃; Al(CH₃)₃ + NH₃; Al(CH₃)₂Cl + NH₃; Al(C₂H₅)₃ + NH₃; |
| | ((CH₃)₃N)AlH₃ + NH₃; ((CH₃)₂(C₂H₅)N)AlH₃ + NH₃ |
| HfO₂ | HfCl₄ + H₂O; Hf[OC(CH₃)₃]₄ + H₂O; [(CH₃)C₂H₅)N]₄Hf + H₂O; |
| | [(CH₃)₂N]₄Hf + H₂O; [(CH₂CH₃)₂N]₄Hf + H₂O |
| Hf₃N₄ | HfCl₄ + NH₃; HF[OC(CH₃)₃]₄ + NH₃; [(CH₃)C₂H₅)N]₄Hf + NH₃; |
| | [(CH₃)₂N]₄Hf + NH₃; [(CH₂CH₃)₂N]₄Hf + NH₃ |
| Si₃N₄ | SiCl₄ + NH₃; Si₂Cl₆ + N₂H₄; SiCl₂H₂ + NH₃-plasma |
| SiO₂ | SiCl₄ + H₂O; Si(NCO)₄ + H₂O; Si(NCO)₄ + N(C₂H₅)₃; Si(C₂H₅O)₄ + H₂O; |
| | CH₃OSi(NCO)₃ + H₂O₂; SiH₄ + O₂; (Bu^{t}O)₃SiOH + Al(CH₃)₃ |
| Ta₂O₅ | TaCl₅ + H₂O; TaCl₅ + Ta(OC₂H₅)₅; TaI₅ + H₂O₂; Ta(OC₂H₅)₅ + H₂O; |
| | Ta(N(CH₃)₂)₅ + H₂O; (CH₃)₃CNTa(N(C₂H₅)₂)₃ + H₂O |
| TiO₂ | TiCl₄ + H₂O; TiCl₄ + H₂O₂; Ti(OC₂H₅)₄ + H₂O; Ti(OCH(CH₃)₂)₄ + H₂O; |
| | [(CH₃C₂H₅)N]₄Ti + H₂O; Ti(N(CH₃)₂)₂(N(CH₂CH₃)₂)₂ + H₂O; |
| | [(C₂H₅)₂N]₄Ti + H₂O; [(CH₃)₂N]₄Ti + H₂O; ((CH₃)₃CO)₄Ti + H₂O |
| TiN | TiCl₄ + NH₃; TiCl₄ + (CH₃)₂NNH₂; TiI₄ + NH₃; Ti(N(CH₃)₂)₄ + NH₃; |
| | Ti(N(C₂H₅)(CH₃))₄ + NH₃; [(CH₃C₂H₅)N]₄Ti + NH₃ |
| ZnO | (C₂H₅)₂Zn + H₂O; (C₂H₅)₂Zn + O₃; (C₂H₅)₂Zn + O₂-plasma; ZnCl₂ + H₂O; |
| | Zn(CH₃)₂ + H₂O |
| ZrO₂ | ZrCl₄ + H₂O; ZrI₄ + H₂O₂; Zr(OC(CH₃)₃)₄ + H₂O; Zr(C₅H₅)₂Cl₂ + O₃; |
| | [(C₂H₅)₂N]₄Zr + H₂O; [(CH₃)₂N]₄Zr + H₂O; Zr(NCH₃C₂H₅)₄ + H₂O |
| Zr₃N₄ | ZrCl₄ + NH₃; Zr(OC(CH₃)₃)₄ + NH₃; Zr(C₅H₅)₂Cl₂ + NH₃; |
| | [(C₂H₅)₂N]₄Zr + NH₃; [(CH₃)₂N]₄Zr + NH₃; Zr(NCH₃C₂H₅)₄ + NH₃ |

In one embodiment, if the passivation layer 14 is an Al₂O₃ thin film, the precursors of the Al₂O₃ thin film can be Trimethylaluminum (Al(CH₃)₃, TMA) and H₂O vapor, where the Al element is from TMA, and the O element is from H₂O.

Taking the deposition of the Al₂O₃-based passivation layer 14 as an example, an atomic layer deposition cycle includes four reaction steps of:

1. Using a carrier gas to carry H₂O molecules into the reaction chamber, thereby the H₂O molecules are absorbed on the upper surface of the substrate to form a layer of OH radicals, where the exposure period is 0.1 second;

2. Using a carrier gas to purge the H₂O molecules not absorbed on the substrate, where the purge time is 5 seconds;

3. Using a carrier gas to carry TMA molecules into the reaction chamber, thereby the TMA molecules react with the OH radicals absorbed on the upper surface of the substrate to form one monolayer of Al₂O₃, wherein a by-product is organic molecules, where the exposure period is 0.1 second; and

4. Using a carrier gas to purge the residual TMA molecules and the by-product due to the reaction, where the purge time is 5 seconds.

The carrier gas can be highly-pure argon or nitrogen. The above four steps, called one cycle of the atomic layer deposition, grows a thin film with single-atomic-layer thickness on the whole area of the substrate. This characteristic is called self-limiting capable of controlling the film thickness with a precision of one atomic layer in the atomic layer deposition. Thus, controlling the number of cycles of atomic layer deposition can precisely control the thickness of the Al₂O₃ passivation layer.

In conclusion, the atomic layer deposition process adopted by the invention has the following advantages: (1) able to control the formation of the material in nano-metric scale; (2) able to control the film thickness more precisely; (3) able to have large-area production; (4) having excellent uniformity; (5) having excellent conformality; (6) having pinhole-free structure; (7) having low defect density; and (8) low deposition temperature, etc.

The deposition of the passivation layer 14 can be performed at a processing temperature ranging from room temperature to 600° C. After the deposition of the passivation layer 14, the passivation layer 14 can be further annealed at an annealing temperature ranging from 300° C. to 1200° C. to improve the quality of the passivation layer 14. In practical applications, the passivation layer 14 can have a thickness in a range of 1 nm to 100 nm.

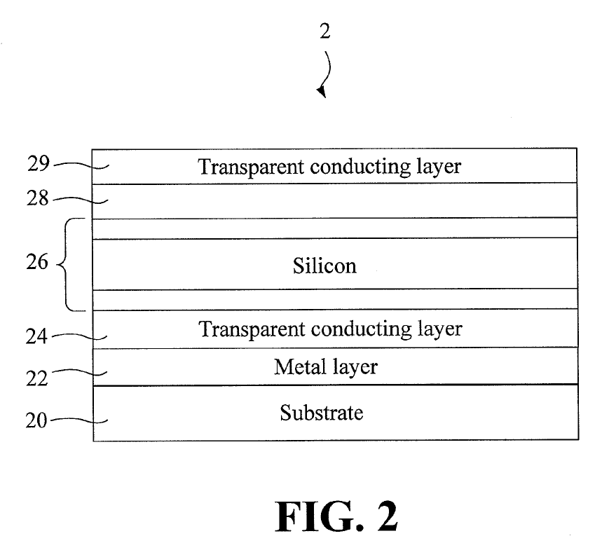

To sufficiently disclose the content of the invention, three embodiments are listed below. Please refer to FIG. 2. FIG. 2 illustrates a sectional view of a thin-film solar cell 2 according to a first embodiment of the invention. The thin-film solar cell 2 in FIG. 2 is a thin-film solar cell having an n-i-p single-junction.

As shown in FIG. 2, the thin-film solar cell 2 includes a substrate 20, a metal layer 22, a transparent conducting layer 24, an n-i-p amorphous structure layer 26, a passivation layer 28, and a transparent conducting layer 29, which are deposited in the sequence in FIG. 2. It is noted that, after the deposition of the n-i-p amorphous structure layer 26, the passivation layer 28 can be deposited on the n-i-p amorphous structure layer 26 by the atomic layer deposition process.

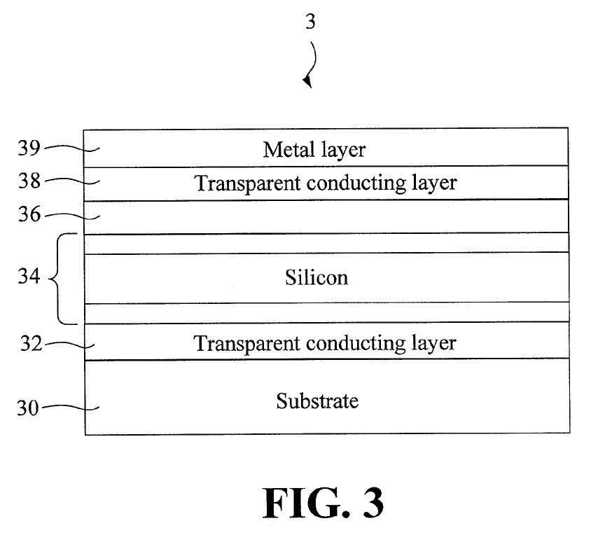

Please refer to FIG. 3. FIG. 3 illustrates a sectional view of a thin-film solar cell 3 according to a second embodiment of the invention. The thin-film solar cell 3 in FIG. 3 is a thin-film solar cell having a p-i-n single-junction.

As shown in FIG. 3, the thin-film solar cell 3 includes a substrate 30, a transparent conducting layer 32, a p-i-n amorphous structure layer 34, a passivation layer 36, a transparent conducting layer 38, and a metal layer 39, which are deposited in the sequence of FIG. 3. It is noted that, after the deposition of the p-i-n amorphous structure layer 34, the passivation layer 36 can be deposited on the p-i-n amorphous structure layer 34 by the atomic layer deposition process. Practically, the thin-film solar cell 3 in FIG. 3 is reversed to function, i.e. light is incident to the substrate 30.

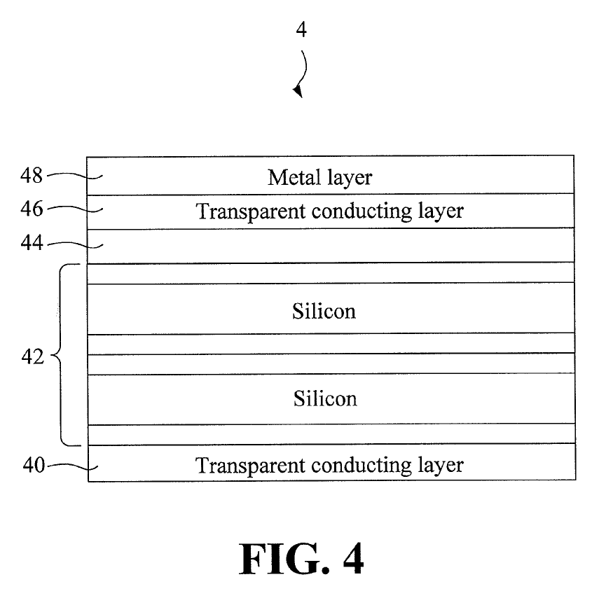

Please refer to FIG. 4. FIG. 4 illustrates a sectional view of a thin-film solar cell 4 according to a third embodiment of the invention. The thin-film solar cell 4 in FIG. 4 is a thin-film solar cell having a tandem junction.

As shown in FIG. 4, the thin-film solar cell 4 includes a transparent conducting layer 40, a p-i-n amorphous/microcrystalline silicon layer 42, a passivation layer 44, a transparent conducting layer 46, and a metal layer 48, which are deposited in the sequence of FIG. 4. It is noted that, after the deposition of the p-i-n amorphous/microcrystalline silicon layer 42, the passivation layer 44 can be deposited by the atomic layer deposition process on the p-i-n amorphous/microcrystalline silicon layer 42.

Please be noted that the explanations of the aforementioned three embodiments are used to describe the characteristic and spirit of the invention, but not to limit the scope of the invention.

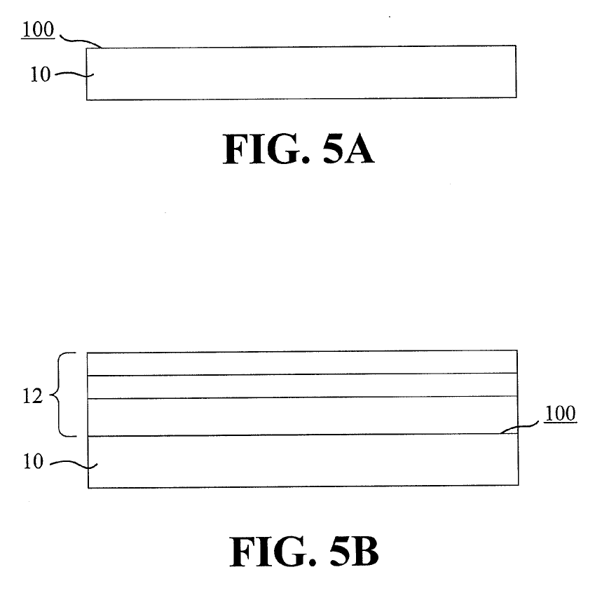

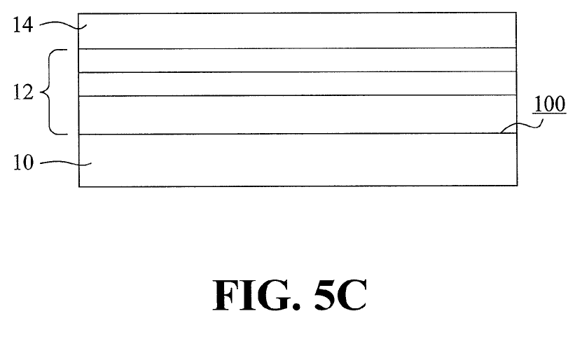

Please refer to FIGS. 5A through 5C and together with FIG. 1. FIGS. 5A through 5C illustrate sectional views for describing the method of fabricating a semiconductor structure combination 1 according to another embodiment of the invention.

First, as shown in FIG. 5A, a substrate 10 having an upper surface 100 is prepared

Next, as shown in FIG. 5B, a multi-layer structure 12 is deposited on the upper surface 100 of the substrate 10. The multi-layer structure 12 includes a p-n junction, a p-i-n junction, an n-i-p junction, a tandem junction or a multi-junction.

Subsequently, as shown in FIG. 5C, by an atomic layer deposition process and/or a plasma-enhanced (or a plasma-assisted) atomic layer deposition process, a passivation layer 14 is deposited on a top-most layer of the multi-layer structure 12.

In practical applications, the passivation layer 14 can be made of Al₂O₃, AlN, HfO₂, Hf₃N₄, Si₃N₄, SiO₂, Ta₂O₅, TiO₂, TiN, ZnO, ZrO₂, Zr₃N₄, other similar compounds, or a mixture of the aforementioned compounds, but not limited herein. In addition, the passivation layer 14 can have a thickness in a range of 1 mm to 100 nm.

Compared to the prior art, inside the semiconductor structure combination for the thin-film solar cell according to the invention, the high-quality surface passivation layer can be deposited, by the atomic layer deposition process, on the silicon thin film with an excellent deposition uniformity and an excellent three-dimensional conformality, to eliminate the effect of dangling bonds and defects. In particular, for the silicon thin film consisting of pinholes and microcrystalline structures, the passivation layer can be deposited, due to the excellent three-dimensional conformality of the atomic layer deposition process, between the pinholes and grain boundaries of the microcrystalline structures in the silicon thin film layer to function effectively.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A semiconductor structure combination for a thin-film solar cell, said semiconductor structure combination comprising:
a substrate having an upper surface;
a multi-layer structure, deposited on the upper surface of the substrate, comprising one selected from the group consisting of a p-n junction, a p-i-n junction, an n-i-p junction, a tandem junction and a multi-junction; and
a passivation layer, deposited by an atomic layer deposition process and/or a plasma-enhanced (or a plasma-assisted) atomic layer deposition process on a top-most layer of the multi-layer structure.

2. The semiconductor structure combination of claim 1, wherein the passivation layer is made of one selected from the group consisting of Al₂O₃, AlN, HfO₂, Hf₃N₄, Si₃N₄, SiO₂, Ta₂O₅, TiO₂, TiN, ZnO, ZrO₂ and Zr₃N₄.

3. The semiconductor structure combination of claim 2, wherein the deposition of the passivation layer is performed at a processing temperature ranging from room temperature to 600° C.

4. The semiconductor structure combination of claim 3, wherein the passivation layer is further annealed at an annealing temperature ranging from 300° C. to 1200° C.

5. The semiconductor structure combination of claim 1, wherein the passivation layer has a thickness in a range of 1 nm to 100 nm.

6. A method of fabricating a semiconductor structure combination for a thin-film solar cell, said method comprising the steps of:
preparing a substrate having an upper surface;
forming a multi-layer structure on the upper surface of the substrate, the multi-layer structure comprising one selected from the group consisting of a p-n junction, a p-i-n junction, an n-i-p junction, a tandem junction and a multi-junction; and
by use of an atomic layer deposition process and/or a plasma-enhanced (or a plasma-assisted) atomic layer deposition process, forming a passivation layer on a top-most layer of the multi-layer structure.

7. The method of claim 6, wherein the passivation layer is made of one selected from the group consisting of Al₂O₃, AlN, HfO₂, Hf₃N₄, Si₃N₄, SiO₂, Ta₂O₅, TiO₂, TiN, ZnO, ZrO₂ and Zr₃N₄.

8. The method of claim 7, wherein the deposition of the passivation layer is performed at a processing temperature ranging from room temperature to 600° C.

9. The method of claim 8, wherein the passivation layer is further annealed at an annealing temperature ranging from 300° C. to 1200° C.

10. The method of claim 6, wherein the passivation layer has a thickness in a range of 1 nm to 100 nm.
